(19) United States
(12) Patent Application Publication
(10) Pub. No.: US 2022/0057958 A1
(43) Pub. Date: Feb. 24, 2022

(54) ADAPTIVE BUFFER PARTITIONING

(71) Applicant: Micron Technology, Inc., Boise, ID (US)

(72) Inventors: Massimiliano Patriarca, Milano (IT); Nicola Del Gatto, Cassina de' Pecchi (IT); Massimiliano Turconi, Gorgonzola (IT); Federica Cresci, Milano (IT)

(21) Appl. No.: 16/950,596

(22) Filed: Nov. 17, 2020

Related U.S. Application Data
(60) Provisional application No. 63/068,949, filed on Aug. 21, 2020.

(51) Int. Cl. G06F 3/06

(52) U.S. Cl. CPC G06F 3/0655; G06F 3/0676; G06F 3/0679; G06F 3/0604

(57) ABSTRACT

Methods, systems, and devices for adaptive buffer partitioning are described. A memory system may include a buffer for storing data (e.g., associated with a read command or a write command received from a host system). For example, the buffer may buffer data associated with a write command prior to storing the data at a memory device of the memory system. In another example, the buffer may buffer data associated with a read command prior to transmitting the data to the host system. In some cases, the buffer may include a first portion configured to store data associated with one or more read commands, a second portion configured to store data associated with one or more write commands, and a third portion configured to store data associated with one or more read commands or one or more write commands.

### CROSS REFERENCE

The present application for patent claims the benefit of U.S. Provisional Patent Application No. 63/068,949 by PATRIARCA et al., entitled “ADAPTIVE BUFFER PARTITIONING,” filed Aug. 21, 2020, assigned to the assignee hereof, and expressly incorporated by reference herein.

### BACKGROUND

The following relates generally to one or more systems for memory and more specifically to adaptive buffer partitioning.

Memory devices are widely used to store information in various electronic devices such as computers, wireless communication devices, cameras, digital displays, and the like. Information is stored by programing memory cells within a memory device to various states. For example, binary memory cells may be programmed to one of two supported states, often denoted by a logic 1 or a logic 0. In some examples, a single memory cell may support more than two states, any one of which may be stored. To access the stored information, a component may read, or sense, at least one stored state in the memory device. To store information, a component may write, or program, the state in the memory device.

Various types of memory devices and memory cells exist, including magnetic hard disks, random access memory (RAM), read-only memory (ROM), dynamic RAM (DRAM), synchronous dynamic RAM (SDRAM), ferroelectric RAM (FeRAM), magnetic RAM (MRAM), resistive RAM (RRAM), flash memory, phase change memory (PCM), self-selecting memory, chalcogenide memory technologies, and others. Memory cells may be volatile or non-volatile. Non-volatile memory, e.g., FeRAM, may maintain their stored logic state for extended periods of time even in the absence of an external power source. Volatile memory devices, e.g., DRAM, may lose their stored state when disconnected from an external power source.

### BRIEF DESCRIPTION OF THE DRAWINGS

FIG. 1 illustrates an example of a system that supports adaptive buffer partitioning in accordance with examples as disclosed herein.

FIG. 2 illustrates an example of a memory device that supports adaptive buffer partitioning in accordance with examples as disclosed herein.

FIG. 3 illustrates an example of a system that supports adaptive buffer partitioning in accordance with examples as disclosed herein.

FIG. 4 illustrates an example of a buffer configuration that supports adaptive buffer partitioning in accordance with examples as disclosed herein.

FIGS. 5 and 6 illustrate example flow diagrams that support adaptive buffer partitioning in accordance with examples as disclosed herein.

FIG. 7 shows a block diagram of a memory system that supports adaptive buffer partitioning in accordance with aspects of the present disclosure.

FIGS. 8 and 9 show flowcharts illustrating a method or methods that support adaptive buffer partitioning in accordance with examples as disclosed herein.

### DETAILED DESCRIPTION

A memory system may receive access commands (e.g., read commands, write commands) from a host system. The memory system may manage a queue of the read commands and write commands using read and write buffer space. That is, data associated with read commands and data associated with write commands may be buffered within the buffer space prior to being transmitted to the host system or stored at a memory device of the memory system, respectively. In some cases, the memory system may use hardware for memory allocation and deallocation including loading data to the buffer and transferring data between the host system and memory devices of the memory system. Additionally, some memory systems may have a fixed allocation of read and write buffer space. In some examples, a total buffer space may be partitioned between read and write buffer space, but partitioning may be static (e.g., permanent) or semi-static (e.g., partitioning may be changed infrequently and with restrictions such as the buffer being cleared for partitioning to occur). In some cases (e.g., for sequential read commands, for sequential write commands), the fixed partitions may not adapt to changing command sequences, especially at high data rates. Thus, speed (e.g., latency, data rate) of the memory system may be impacted based on an availability of space within the buffer space to store data associated with read commands or write commands.

In examples described herein, the memory system may include a buffer with adaptive partitioning. For example, the buffer may include a first portion that is dedicated as a read buffer (e.g., for storing data associated with read commands), a second portion that is dedicated as a write buffer (e.g., for storing data associated with write commands), and a third portion that can be dynamically allocated to store data associated with either read or write commands. In some cases, the memory system may include firmware that determines an amount of space within the buffer that is available for data associated with read commands (e.g., upon receiving a read command) or data associated with write commands (e.g., upon receiving a write command). The memory system may determine the amount of space that is available based on the amounts of the first, second, and third portions of the buffer that are being used based on previously-received read or write commands. Additionally, firmware at the memory system may send indications that space is available for processing the command (e.g., receiving the data for a write command, retrieving the data from the memory devices for a read command).

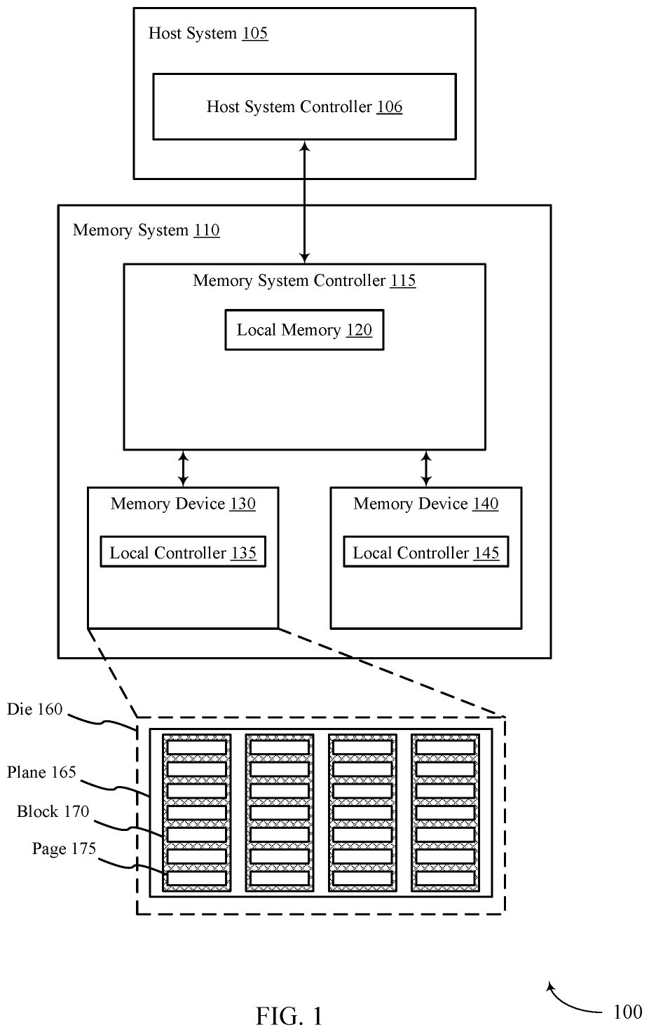

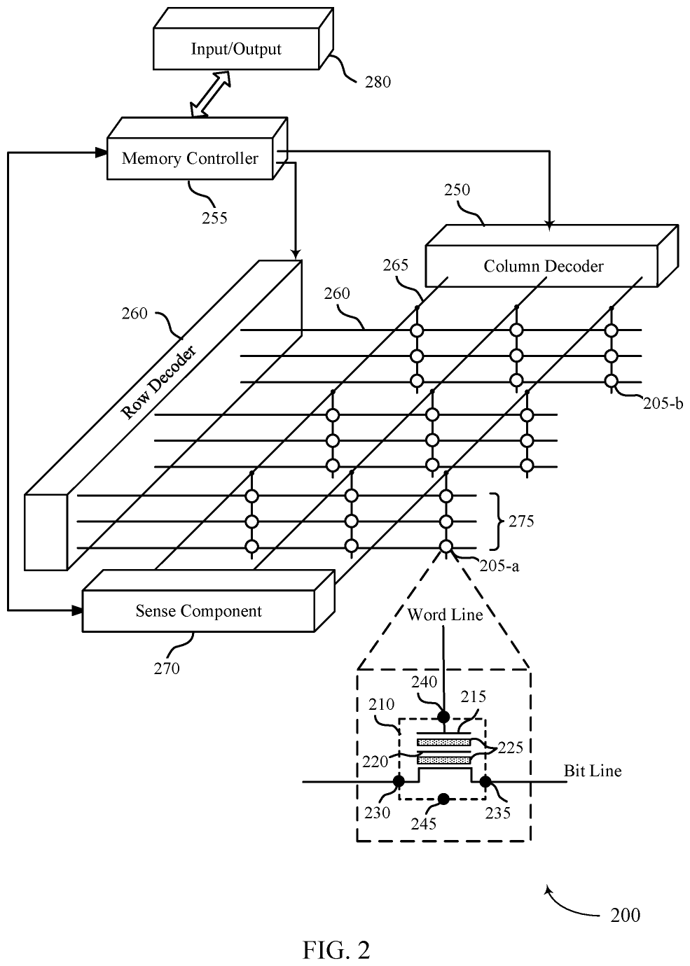

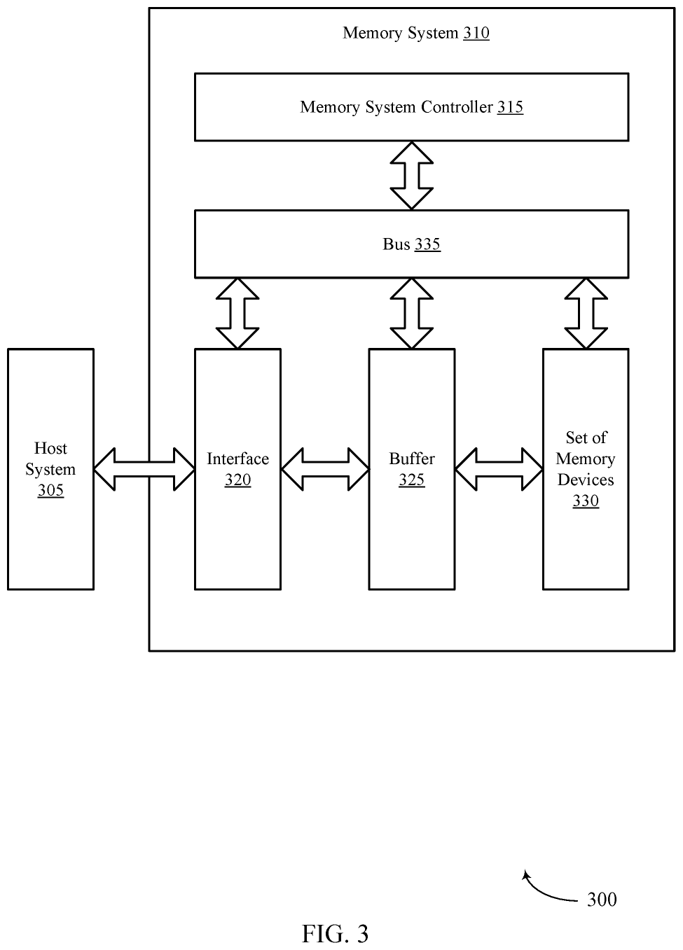

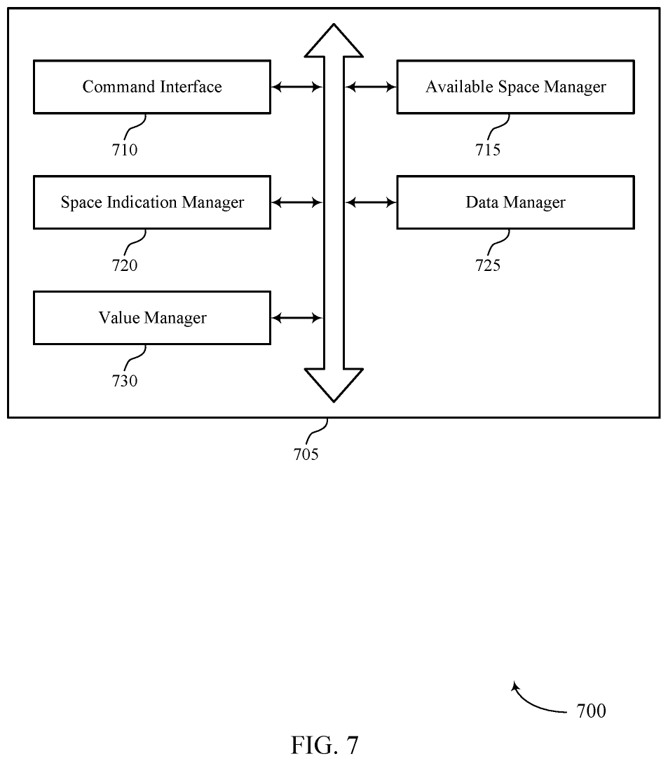

Features of the disclosure are initially described in the context of systems and dies as described with reference to FIGS. 1 and 2. Features of the disclosure are described in the context of a system, a buffer configuration, and flow diagrams as described with reference to FIGS. 3-6. These and other features of the disclosure are further illustrated by and described with reference to an apparatus diagram and flowcharts that relate to adaptive buffer partitioning as described with reference to FIGS. 7-9.

FIG. 1 illustrates an example of a system 100 that supports adaptive buffer partitioning in accordance with examples as disclosed herein. The system 100 includes a host system 105 coupled with a memory system 110.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other possibilities.

The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

The system 100 may include a host system 105, which may be coupled with the memory system 110. In some examples, this coupling may include an interface with a host system controller 106, which may be an example of a control component configured to cause the host system 105 to perform various operations in accordance with examples as described herein. The host system 105 may include one or more devices, and in some cases may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., UFS Controller, PCIe controller, SATA controller). The host system 105 may use the memory system 110, for example, to write data to the memory system 110 and read data from the memory system 110. Although one memory system 110 is shown in FIG. 1, it is to be understood that the host system 105 may be coupled with any quantity of memory systems 110.

The host system 105 may be coupled with the memory system 110 via at least one physical host interface. The host system 105 and the memory system 110 may in some cases be configured to communicate via a physical host interface using an associated protocol (e.g., to exchange or otherwise communicate control, address, data, and other signals between the memory system 110 and the host system 105). Examples of a physical host interface may include, but are not limited to, a serial advanced technology attachment (SATA) interface, a UFS interface, an eMMC interface, a peripheral component interconnect express (PCIe) interface, USB interface, Fiber Channel, Small Computer System Interface (SCSI), Serial Attached SCSI (SAS), Double Data Rate (DDR), a dual in-line memory module (DIMM) interface (e.g., DIMM socket interface that supports DDR), Open NAND Flash Interface (ONFI), Low Power Double Data Rate (LPDDR). In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 or memory device 140 included in the memory system 110, or via a respective physical host interface for each type of memory device 130 or memory device 140 included in the memory system 110.

Memory system 110 may include a memory system controller 115, a memory device 130, and a memory device 140. A memory device 130 may include one or more memory arrays of a first type of memory cells (e.g., a type of non-volatile memory cells), and a memory device 140 may include one or more memory arrays of a second type of memory cells (e.g., a type of volatile memory cells). Although one memory device 130 and one memory device 140 are shown in the example of FIG. 1, it is to be understood that memory system 110 may include any quantity of memory devices 130 and memory devices 140, and that, in some cases, memory system 110 may lack either a memory device 130 or a memory device 140.

The memory system controller 115 may be coupled with and communicate with the host system 105 (e.g., via the physical host interface), and may be an example of a control component configured to cause the memory system 110 to perform various operations in accordance with examples as described herein. The memory system controller 115 may also be coupled with and communicate with memory devices 130 or memory devices 140 to perform operations such as reading data, writing data, erasing data, or refreshing data at a memory device 130 or a memory device 140, and other such operations, which may generically be referred to as access operations. In some cases, the memory system controller 115 may receive commands from the host system 105 and communicate with one or more memory devices 130 or memory devices 140 to execute such commands (e.g., at memory arrays within the one or more memory devices 130 or memory devices 140). For example, the memory system controller 115 may receive commands or operations from the host system 105 and may convert the commands or operations into instructions or appropriate commands to achieve the desired access of the memory devices 130 or memory devices 140. And in some cases, the memory system controller 115 may exchange data with the host system 105 and with one or more memory devices 130 or memory devices 140 (e.g., in response to or otherwise in association with commands from the host system 105). For example, the memory system controller 115 may convert responses (e.g., data packets or other signals) associated with the memory devices 130 or memory devices 140 into corresponding signals for the host system 105.

The memory system controller 115 may be configured for other operations associated with the memory devices 130 or memory devices 140. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130 or memory devices 140.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally or alternatively include static random access memory (SRAM) or other memory that may be used by the memory system controller 115 for internal storage or calculations, for example, related to the functions ascribed herein to the memory system controller 115. Additionally or alternatively, the local memory 120 may serve as a cache for the memory system controller 115.

Although the example of memory system 110 in FIG. 1 has been illustrated as including the memory system controller 115, in some cases, a memory system 110 may not include a memory system controller 115. For example, the memory system 110 may additionally or alternatively rely upon an external controller (e.g., implemented by the host system 105) or one or more local controllers 135 or local controllers 145, which may be internal to memory devices 130 or memory devices 140, respectively, to perform the functions ascribed herein to the memory system controller 115. In general, one or more functions ascribed herein to the memory system controller 115 may in some cases instead be performed by the host system 105, a local controller 135, or a local controller 145, or any combination thereof.

A memory device 140 may include one or more arrays of volatile memory cells. For example, a memory device 140 may include random access memory (RAM) memory cells, such as dynamic RAM (DRAM) memory cells and synchronous DRAM (SDRAM) memory cells. In some examples, a memory device 140 may support random access operations (e.g., by the host system 105) with reduced latency relative to a memory device 130, or may offer one or more other performance differences relative to a memory device 130.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric RAM (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), and electrically erasable programmable ROM (EEPROM).

In some examples, a memory device 130 or a memory device 140 may include (e.g., on a same die or within a same package) a local controller 135 or a local controller 145, respectively, which may execute operations on one or more memory cells of the memory device 130 or the memory device 140. A local controller 135 or a local controller 145 may operate in conjunction with a memory system controller 115 or may perform one or more functions ascribed herein to the memory system controller 115. In some cases, a memory device 130 or a memory device 140 that includes a local controller 135 or a local controller 145 may be referred to as a managed memory device and may include a memory array and related circuitry combined with a local (e.g., on-die or in-package) controller (e.g., local controller 135 or local controller 145). An example of a managed memory device is a managed NAND (MNAND) device.

In some cases, a memory device 130 may be or include a NAND device (e.g., NAND flash device). A memory device 130 may be or include a memory die 160. For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170, and in some cases, concurrent operations may take place within different planes 165. For example, concurrent operations may be performed on memory cells within different blocks 170 so long as the different blocks 170 are in different planes 165. In some cases, performing concurrent operations in different planes 165 may be subject to one or more restrictions, such as identical operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at the page level of granularity) but may be erased at a second level of granularity (e.g., at the block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may in some cases not be updated until the entire block 170 that includes the page 175 has been erased.

In some cases, a memory system controller 115, a local controller 135, or a local controller 145 may perform operations (e.g., as part of one or more media management algorithms) for a memory device 130 or a memory device 140, such as wear leveling, background refresh, garbage collection, scrub, block scans, health monitoring, or others, or any combination of these operations. In some examples, the host system 105 may initiate garbage collection operations by sending a host active garbage collection (HAGC) command. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

The system 100 may include any quantity of non-transitory computer readable media that support adaptive buffer partitioning. For example, the host system 105, the memory system controller 115, a memory device 130, or a memory device 140 may include or otherwise may access one or more non-transitory computer readable media storing instructions (e.g., firmware) for performing the functions ascribed herein to the host system 105, memory system controller 115, memory device 130, or memory device 140. For example, such instructions, when executed by the host system 105 (e.g., by the host system controller 106), by the memory system controller 115, by a memory device 130 (e.g., by a local controller 135), or by a memory device 140 (e.g., by a local controller 145), may cause the host system 105, memory system controller 115, memory device 130, or memory device 140 to perform one or more associated functions as described herein.

In examples described herein, the memory system 110 may include a buffer with adaptive partitioning. For example, the buffer may include a first portion that is dedicated as a read buffer (e.g., for storing data associated with read commands), a second portion that is dedicated as a write buffer (e.g., for storing data associated with write commands), and a third portion that can be dynamically allocated to store data associated with either read or write commands. In some cases, the memory system 110 may include firmware (e.g., at the memory system controller 115) that determines an amount of space within the buffer that is available for data associated with read commands (e.g., upon receiving a read command) or data associated with write commands (e.g., upon receiving a write command). The firmware may determine the amount of space that is available based on the amount of the third portion of the buffer that is full (e.g., occupied) based on previously-received read or write commands. Additionally, firmware at the memory system 110 may send indications that space is available for processing the command (e.g., receiving the data for a write command, retrieving the data from the memory devices for a read command).

FIG. 2 illustrates an example of a memory device 200 that supports adaptive buffer partitioning in accordance with examples as disclosed herein. In some cases, the memory device 200 may be an example of a memory device 130 as described with reference to FIG. 1. FIG. 2 is an illustrative representation of various components and features of the memory device 200. As such, it should be appreciated that the components and features of the memory device 200 are shown to illustrate functional interrelationships, and not necessarily actual physical positions within the memory device 200. Further, although some elements included in FIG. 2 are labeled with a numeric indicator, some other corresponding elements are not labeled, even though they are the same or would be understood to be similar, in an effort to increase visibility and clarity of the depicted features.

The memory device 200 may include one or more memory cells, such as memory cell 205-a and memory cell 205-b. A memory cell 205 may be, for example, a flash or other type of NAND memory cell, such as in the blow-up diagram of memory cell 205-a.

Each memory cell 205 may be programmed to store a logic value representing one or more bits of information. In some cases, a single memory cell 205—such as an SLC memory cell 205—may be programmed to one of two supported states and thus may store one bit of information at a time (e.g., a logic 0 or a logic 1). In other cases, a single memory cell 205—such as an MLC, TLC, QLC, or other type of multiple-level memory cell 205 may be programmed to one of more than two supported states and thus may store more than one bit of information at a time. In some examples, a single MLC memory cell 205 may be programmed to one of four supported states and thus may store two bits of information at a time corresponding to one of four logic values (e.g., a logic 00, a logic 01, a logic 10, or a logic 11). In some examples, a single TLC memory cell 205 may be programmed to one of eight supported states and thus may store three bits of information at a time corresponding to one of eight logic values (e.g., 000, 001, 010, 011, 100, 101, 110, or 111). In some examples, a single QLC memory cell 205 may be programmed to one of sixteen supported states and thus may store four bits of information at a time corresponding to one of sixteen logic values (e.g., 0000, 0001, . . . 1111).

In some cases, a multiple-level memory cell 205 (e.g., an MLC memory cell, a TLC memory cell, a QLC memory cell) may be physically different than an SLC cell. For example, a multiple-level memory cell 205 may use a different cell geometry or may be fabricated using different materials. In some cases, a multiple-level memory cell 205 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

Different types of memory cells 205 may store information in different ways. In a DRAM memory array, for example, each memory cell 205 may include a capacitor that includes a dielectric material (e.g., an insulator) to store a charge representative of a programmable state and thus the stored information. In an FeRAM memory array, as another example, each memory cell 205 may include a capacitor that includes a ferroelectric material to store a charge or a polarization representative of a programmable state and thus the stored information.

In some NAND memory arrays (e.g., flash arrays), each memory cell 205 may include a transistor that has a floating gate or a dielectric material for storing an amount of charge representative of the logic value. For example, the blow-up in FIG. 2 illustrates a NAND memory cell 205-a that includes a transistor 210 (e.g., a metal-oxide-semiconductor (MOS) transistor) that may be used to store a logic value. The transistor 210 has a control gate 215 and may also include a floating gate 220, where the floating gate 220 is sandwiched between two portions of dielectric material 225. Transistor 210 includes a first node 230 (e.g., a source or drain) and a second node 235 (e.g., a drain or source). A logic value may be stored in transistor 210 by placing (e.g., writing, storing) a quantity of electrons (e.g., an amount of charge) on floating gate 220. The amount of charge to be stored on the floating gate 220 may depend on the logic value to be stored. The charge stored on floating gate 220 may affect the threshold voltage of transistor 210, thereby affecting the amount of current that flows through transistor 210 when transistor 210 is activated (e.g., when a voltage is applied to the control gate 215).

A logic value stored in transistor 210 may be sensed (e.g., as part of a read operation) by applying a voltage to the control gate 215 (e.g., to control node 240, via the word line 260) to activate transistor 210 and measuring (e.g., detecting, sensing) the resulting amount of current that flows through the first node 230 or the second node 235 (e.g., via a digit line 265). For example, a sense component 270 may determine whether an SLC memory cell 205 stores a logic 0 or a logic 1 in a binary manner (e.g., based on a presence or absence of a current through the memory cell 205 when a read voltage is applied to the control gate 215, or based on whether the current is above or below a threshold current). For a multiple-level memory cell 205, a sense component 270 may determine a logic value stored in the memory cell 205 based on various intermediate threshold levels of current when a read voltage is applied to the control gate 215. In one example of a multiple-level architecture, a sense component 270 may determine the logic value of a TLC memory cell 205 based on eight different levels of current, or ranges of current, that define the eight potential logic values that could be stored by the TLC memory cell 205.

An SLC memory cell 205 may be written by applying one of two voltages (e.g., a voltage above a threshold or a voltage below a threshold) to memory cell 205 to store, or not store, an electric charge on the floating gate 220 and thereby cause the memory cell 205 store one of two possible logic values. For example, when a first voltage is applied to the control node 240 (e.g., via the word line 260) relative to a bulk node 245 for the transistor 210 (e.g., when the control node 240 is at a higher voltage than the bulk), electrons may tunnel into the floating gate 220. In some cases, the bulk node 245 may alternatively be referred to as a body node. Injection of electrons into the floating gate 220 may be referred to as programing the memory cell 205 and may occur as part of a program operation. A programmed memory cell may, in some cases, be considered as storing a logic 0. When a second voltage is applied to the control node 240 (e.g., via the word line 260) relative to the bulk node 245 for the transistor 210 (e.g., when the control node 240 is at a lower voltage than the bulk node 245), electrons may leave the floating gate 220. Removal of electrons from the floating gate 220 may be referred to as erasing the memory cell 205 and may occur as part of an erase operation. An erased memory cell may, in some cases, be considered as storing a logic 1. In some cases, memory cells 205 may be programmed at a page 175 level of granularity due to memory cells 205 of a page 175 sharing a common word line 260, and memory cells 205 may be erased at a block 170 level of granularity due to memory cells 205 of a block sharing commonly biased bulk nodes 245.

In contrast to writing an SLC memory cell 205, writing a multiple-level (e.g., MLC, TLC, or QLC) memory cell 205 may involve applying different voltages to the memory cell 205 (e.g., to the control node 240 or bulk node 245 thereof) at a finer level of granularity to more finely control the amount of charge stored on the floating gate 220, thereby enabling a larger set of logic values to be represented. Thus, multiple-level memory cells 205 may provide greater density of storage relative to SLC memory cells 205 but may, in some cases, involve narrower read or write margins or greater complexities for supporting circuitry.

A charge-trapping NAND memory cell 205 may operate similarly to a floating-gate NAND memory cell 205 but, instead of or in addition to storing a charge on a floating gate 220, a charge-trapping NAND memory cell 205 may store a charge representing a logic state in a dielectric material below the control gate 215. Thus, a charge-trapping NAND memory cell 205 may or may not include a floating gate 220.

In some examples, each row of memory cells 205 may be connected to a corresponding word line 260, and each column of memory cells 205 may be connected to a corresponding digit line 265. Thus, one memory cell 205 may be located at the intersection of a word line 260 and a digit line 265. This intersection may be referred to as an address of a memory cell 205. Digit lines 265 may alternatively be referred to as bit lines. In some cases, word lines 260 and digit lines 265 may be substantially perpendicular to one another and may create an array of memory cells 205. In some cases, word lines 260 and digit lines 265 may be generically referred to as access lines or select lines.

In some cases, memory device 200 may include a three-dimensional (3D) memory array, where multiple two-dimensional (2D) memory arrays may be formed on top of one another. This may increase the quantity of memory cells 205 that may be placed or fabricated on a single die or substrate as compared with 2D arrays, which, in turn, may reduce production costs, or increase the performance of the memory array, or both. In the example of FIG. 2, memory device 200 includes multiple levels (e.g., decks) of memory cell 205. The levels may, in some examples, be separated by an electrically insulating material. Each level may be aligned or positioned so that memory cells 205 may be aligned (e.g., exactly aligned, overlapping, or approximately aligned) with one another across each level, forming a memory cell stack 275. In some cases, a memory cell stack 275 may be referred to as a string of memory cells 205.

Accessing memory cells 205 may be controlled through row decoder 260 and column decoder 250. For example, row decoder 260 may receive a row address from memory controller 255 and activate an appropriate word line 260 based on the received row address. Similarly, column decoder 250 may receive a column address from memory controller 255 and activate an appropriate digit line 265. Thus, by activating one word line 260 and one digit line 265, one memory cell 205 may be accessed.

Upon accessing, a memory cell 205 may be read, or sensed, by sense component 270. For example, sense component 270 may be configured to determine the stored logic value of memory cell 205 based on a signal generated by accessing memory cell 205. The signal may include a current, a voltage, or both a current and a voltage on the digit line 265 for the memory cell 205 and may depend on the logic value stored by the memory cell 205. The sense component 270 may include various transistors or amplifiers configured to detect and amplify a signal (e.g., a current or voltage) on a digit line 265. The logic value of memory cell 205 as detected by the sense component 270 may be output via input/output 280. In some cases, sense component 270 may be a part of column decoder 250 or row decoder 260, or sense component 270 may otherwise be connected to or in electronic communication with column decoder 250 or row decoder 260.

A memory cell 205 may be programmed or written by activating the relevant word line 260 and digit line 265 to enable a logic value (e.g., representing one or more bits of information) to be stored in the memory cell 205. A column decoder 250 or a row decoder 260 may accept data, for example from input/output 280, to be written to the memory cells 205. As previously discussed, in the case of NAND memory, such as flash memory used in some NAND and 3D NAND memory devices, a memory cell 205 may be written by storing electrons in a floating gate or an insulating material.

A memory controller 255 may control the operation (e.g., read, write, re-write, refresh) of memory cells 205 through the various components, for example, row decoder 260, column decoder 250, and sense component 270. In some cases, one or more of row decoder 260, column decoder 250, and sense component 270 may be co-located with memory controller 255. A memory controller 255 may generate row and column address signals in order to activate the desired word line 260 and digit line 265. In some examples, a memory controller 255 may generate and control various voltages or currents used during the operation of memory device 200.

In examples described herein, the input/output 280 may be in communication with a buffer having adaptive partitioning. The buffer may include a first portion that is dedicated as a read buffer (e.g., for storing data associated with read commands), a second portion that is dedicated as a write buffer (e.g., for storing data associated with write commands), and a third portion that can be dynamically allocated to store data associated with either read or write commands. Thus, the input/output 280 may receive data to be stored at the memory device 200 from the buffer (e.g., based on a write command). That is, the buffer may be storing the data associated with the write command in the second portion or the third portion and may communicate the data to the input/output 280 to be stored at the memory device 200. Additionally, the input/output 280 may transfer data to the buffer (e.g., from the memory device 200) based on a read command. In some cases, the input/output 280 may transfer the data to the buffer after receiving the read command (e.g., from a memory system controller 115 as described with reference to FIG. 1) based on the buffer having sufficient space for storing the data associated with the read command.

FIG. 3 illustrates an example of a system 300 that supports adaptive buffer partitioning in accordance with examples as disclosed herein. In some cases, the system 300 may be an example of a system 100 as described with reference to FIG. 1. Additionally, system 300 may implement aspects of system 100 and memory device 200 as described with reference to FIGS. 1 and 2. For example, the host system 305 may be an example of the host system 105, the memory system 310 may be an example of the memory system 110, and the memory system controller 315 may be an example of the memory system controller 115. Further, the set of memory devices 330 may include one or more memory devices as described with reference to FIGS. 1 and 2. For example, the set of memory devices 330 may include NAND memory, PCM, self-selecting memory, 3D XPoint, other chalcogenide-based memories, FERAM, MRAM, NOR (e.g., NOR flash) memory, STT-MRAM, CBRAM, RRAM, or OxRAM.

The memory system 310 may additionally include an interface 320, a buffer 325, and a bus 335. The set of memory devices 330 may communicate with the memory system controller 315 and the buffer 325 directly or via a bus 335 using a protocol specific to each type of memory device within the set of memory devices 330. Additionally, the buffer 325 and the interface 320 may communicate (e.g., with each other, with the memory system controller 315) using a protocol specific to the memory system 310.

The memory system 310 may be in communication with the host system 305 by the interface 320 (e.g., a front end of the memory system 310). In some cases, the interface 320 may manage a communication of data and commands between the host system 305 and the memory system 310. That is, the interface 320 may communicate with the host system 305 according to a protocol (e.g., a universal flash storage (UFS) protocol, eMMC protocol, PCIe). In some cases, the host system 305 may transmit one or more read or write commands to the memory system 310 via the interface 320. The interface 320 may communicate the commands to the memory system controller 315 (e.g., directly or via the bus 335). In the example of the host system 305 transmitting a write command to the memory system 310, the host system 305 may additionally transmit data to the memory system 310 via the interface 320. In the example of the host system 305 transmitting a read command to the memory system 310, the memory system 310 may transmit data to the host system 305 via the interface 320.

When performing access operations (e.g., executing read commands or write commands received from the host system 305), the memory system 310 may buffer data associated with the access operations in the buffer 325 (e.g., a middle end of the memory system 310). That is, in a case that the host system 305 transmits a read command to the memory system 310, the memory system controller 315 may facilitate a transfer of the data associated with the read command from a memory device of the set of memory devices 330 to the buffer 325. The buffer 325 may temporarily store the data prior to transmitting the data to the host system 305 via the interface 320. Additionally, in a case that the host system 305 transmits a write command to the memory system 310, the memory system controller 315 may facilitate a transmission of the data associated with the write command from the host system 305 to the buffer 325 (e.g., via the interface 320). The buffer 325 may temporarily store the data prior to transferring the data to one of the memory devices of the set of memory devices 330. The temporary storage of data within the buffer 325 may refer to the storage of the data in the buffer 325 during the execution of access commands. That is, upon a completion of the access command, the data may no longer be maintained in the buffer 325 (e.g., may be overwritten with data for additional read or write commands). In addition, the buffer 325 may be a non-cache buffer. That is, data may not be read directly from the buffer 325 by the host system 305. For example, read commands may be placed on the queue without an operation to match the address to addresses already in the buffer (e.g., without a cache address match or lookup operation).

The memory system controller 315 may additionally store a queue including the access commands (e.g., read commands, write commands) that are associated with data currently stored in the buffer 325. That is, while the buffer 325 is storing data associated with an access command, the memory system controller 315 may store that access command in the queue. In some cases, each command in the queue may be associated with an address at the buffer 325. That is, pointers may be maintained that indicate where in the buffer 325 the data associated with each command is stored. Thus, when the command is removed from the queue (e.g., due to a completion of the command), the address previously storing the data associated with that command may be available to store data associated with a new command. In some cases, buffer address management (e.g., pointers to address locations in the buffer) may be performed by hardware circuits (e.g., logic gate circuits).

The buffer 325 may utilize adaptive partitioning to store data associated with read commands and write commands. That is, the buffer 325 may include a first portion that is dedicated as a read buffer (e.g., for storing data associated with read commands), a second portion that is dedicated as a write buffer (e.g., for storing data associated with write commands), and a third portion that can be dynamically allocated to store data associated with either read or write commands. Thus, based on commands received from the host system 305, the third portion of the buffer 325 may be storing data associated with read commands, data associated with write commands, or a combination of data associated with read commands and data associated with write commands. In some cases, the adaptive partitioning of the buffer 325 (e.g., the third portion of the buffer 325 that is configured to store data associated with read commands or write commands) may decrease a likelihood that the buffer 325 does not have sufficient space for data associated with a command received from the host system when compared to a buffer that has static or semi-static partitioning.

The memory system controller 315 may include firmware (e.g., controller firmware) for determining an amount of space within the buffer 325 that is available for storing data associated with a received command. For example, if the host system 305 transmits a write command to the memory system 310, the memory system controller 315 may determine an amount of space within the buffer 325 that is available to store data associated with a write command. That is, the memory system controller 315 may determine an amount of space available within the first portion of the buffer 325 and the third portion of the buffer 325. If the memory system controller 315 determines that there is sufficient space available within the buffer 325 to store the data associated with the write command, the memory system 310 may transmit an indication of the availability to the host system via the interface 320 (e.g., a ready to transfer indication). Then, the interface 320 may transfer the data associated with the write command to the buffer 325 for temporary storage. Additionally, the memory system controller 315 may add the write command to the queue.

In an example where the host system 305 transmits a read command to the memory system 310, the memory system controller 315 may determine an amount of space within the buffer 325 that is available to store data associated with a read command. That is, the memory system controller 315 may determine an amount of space available within the second portion of the buffer 325 and the third portion of the buffer 325. If the memory system controller 315 determines that there is sufficient space available within the buffer 325 to store the data associated with the read command, the memory system 310 issue a read command to a memory device within the set of memory devices. Then, the memory device of the set of memory devices 330 may transfer the data associated with the read command to the buffer 325 for temporary storage. Additionally, the memory system controller 315 may add the read command to the queue.

Data may additionally be transferred from the buffer 325. For example, the memory system controller 315 may include a queue of previously-received read commands and write commands. The memory system controller 315 may complete an execution of the previously-received commands according to an order (e.g., a first-in, first-out order, according to the order of the queue) and may subsequently remove the commands from the queue. To complete an execution of a write command, the memory system controller 315 may transfer data associated with the write command that is being temporarily stored in the buffer 325 to a memory device of the set of memory devices 330 for storage. Upon completion of the write command, the memory system controller 315 may remove the write command from the queue. To complete an execution of a read command, the memory system controller 315 may transmit data associated with the read command that is being temporarily stored in the buffer 325 to the host system 305 via the interface 320. Upon completion of the read command, the memory system controller 315 may remove the read command from the queue.

The memory system controller 315 may additionally be configured for operations associated with the set of memory devices 330. For example, the memory system controller 315 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 305 and physical addresses (e.g., physical block addresses) associated with memory cells within the set of memory devices 330. That is, the host system 305 may issue commands indicating one or more LBAs and the memory system controller 315 may identify one or more physical block addresses indicated by the LBAs. In some cases, one or more contiguous LBAs may be noncontiguous physical block addresses.

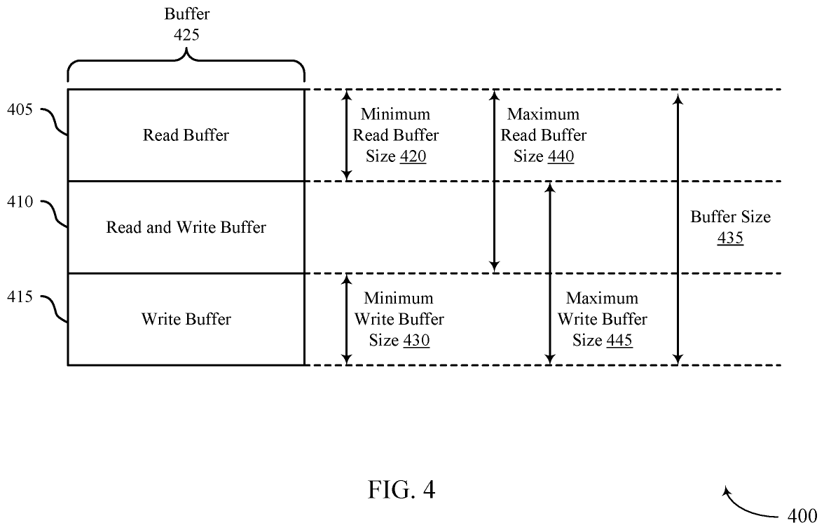

FIG. 4 illustrates an example of a buffer configuration 400 that supports adaptive buffer partitioning in accordance with examples as disclosed herein. The buffer configuration 400 (e.g., of the buffer 425) may be an example configuration of a buffer within a memory system as described with reference to FIGS. 1 through 3. The buffer 425 may include a read buffer 405 (e.g., for storing data associated with read commands), a read and write buffer 410 (e.g., for storing data associated with either read commands or write commands), and a write buffer 415 (e.g., for storing data associated with write commands).

The buffer 425 may have a total buffer size 435, where the buffer size 435 corresponds to a maximum quantity of data that the buffer 425 may store. The buffer 425 may additionally have a minimum read buffer size 420. The minimum read buffer size 420 corresponds to a portion of the buffer 425 that is dedicated for storing data associated with read commands (e.g., a size of the read buffer 405). Further, the buffer 425 may be associated with a minimum write buffer size 430. The minimum write buffer size 430 corresponds to a portion of the buffer 425 that is dedicated for storing data associated with write commands (e.g., a size of the write buffer 415).

The maximum read buffer size 440 may correspond to a maximum amount of data associated with read commands that the buffer 425 may be configured to store. That is, the maximum read buffer size 440 may correspond to a size of the read buffer 405 and the read and write buffer 410. The maximum write buffer size 445 may correspond to a maximum amount of data associated with write commands that the buffer 425 may be configured to store. That is, the maximum write buffer size 445 may correspond to the size of the read and write buffer 410 and the write buffer 415.

During an initialization of the buffer 425 (e.g., and the buffer partitions), a controller associated with the buffer 425 (e.g., a memory system controller as described herein) may determine a quantity of space available within the buffer 425 for storing data associated with read commands and write commands. For example, the controller may determine that the space within the buffer 425 available for storing data associated with read commands is equal to the maximum read buffer size 440 as the read buffer 405 and the read and write buffer 410 are empty during the initialization. Additionally, the controller may determine that the space within the buffer available for storing data associated with write commands is equal to the maximum write buffer size 445 as the read and write buffer 410 and the write buffer 415 are empty during the initialization. In some cases, the controller may store the indication of the available space within the buffer 425 for both read commands and write commands in separate counters at the controller. In some other cases, the controller may store an indication of the amount of space within the buffer 425 currently used to store data associated read commands in a first counter and an indication of the amount of space within the buffer 425 currently used to store data associated with write commands in a second counter. During an initialization, both the first and second counters may be initialized to zero (e.g., indicating that the buffer 425 is not storing any data associated with read or write commands).

When the memory system (e.g., the memory system that includes the buffer 425) receives a write command, the controller may compare a size of data associated with the write command to the space within the buffer 425 that is available for storing data associated with write commands. For example, the controller may compare the size of the data associated with the write command to the value stored in the counter at the controller (e.g., indicating the amount of space within the buffer 425 that is available for storing data associated with write commands). In some cases, the controller may determine a difference between the maximum write buffer size 445 and the combination of a value stored in the counter (e.g., indicating the amount of space within the buffer 425 that is currently used for storing data associated with write commands) and the quantity of data within the read and write buffer 410 associated with read commands, thus determining the amount of space available in the buffer 425 for storing data associated with write commands. In a case that the controller determines there is sufficient space in the buffer 425 for storing the data associated with the write command, the controller may transmit, to a host system, an indication of the availability. The controller may also indicate to a buffer manager (e.g., a hardware layer that allocates/deallocates space in buffer 425) to allocate space and receive the data from the memory system for storage in the buffer 425. The host system may then transmit the data to the memory system for temporary storage at the buffer 425.

The controller may update the value of the counter indicating the amount of space within the buffer that is available for storing data associated with write commands. For example, the controller may decrement the value of the counter according to the size of the data (e.g., subtract the size of the data from the value of the counter). In some cases, the controller may increment the value of the counter indicating the amount of space within the buffer 425 currently used for storing data associated with write commands. In some cases, the controller may update the value of the counter upon transmitting the indication of the availability within the buffer 425 to the host system. Additionally, the controller may update the value of the counter indicating the amount of space within the buffer that is available for storing data associated with read commands (e.g., if the data associated with the write command is stored in the read and write buffer 410).

When the memory system (e.g., the memory system that includes the buffer 425) receives a read command, the controller may compare a size of data associated with the read command to the space within the buffer 425 that is available for storing data associated with read commands. For example, the controller may compare the size of the data associated with the read command to the value stored in the counter at the controller (e.g., indicating the amount of space within the buffer 425 that is available for storing data associated with read commands). In some cases, the controller may determine a difference between the maximum read buffer size 440 and the combination of a value stored in the counter (e.g., indicating the amount of space within the buffer 425 that is currently used for storing data associated with read commands) and the quantity of data within the read and write buffer 410 associated with write commands, thus determining the amount of space available in the buffer 425 for storing data associated with read commands. In a case that the controller determines there is sufficient space in the buffer 425 for storing the data associated with the read command, the controller may issue a read command to a memory device at the memory system. The memory device may then transfer the data to the buffer 425.

The controller may update the value of the counter indicating the amount of space within the buffer that is available for storing data associated with read commands. For example, the controller may decrement the value of the counter according to the size of the data (e.g., may subtract the size of the data from the value of the counter). In some cases, the controller may increment the value of the counter indicating the amount of space within the buffer 425 currently used for storing data associated with read commands. In some cases, the controller may update the value of the counter upon transferring the data associated with the read command to the buffer 425. Additionally, the controller may update the value of the counter indicating the amount of space within the buffer that is available for storing data associated with write commands (e.g., if the data associated with the read command is stored in the read and write buffer 410). Thus, the amount of space within the buffer 425 that is available for storing data associated with read commands or write commands is based on an amount of data associated with previously-received read commands and write commands (e.g., that are still in a queue associated with incomplete read commands and write commands).

The controller may include a queue of previously-received read commands and write commands associated with data being stored in the buffer 425 (e.g., incomplete read and write commands). The controller may complete an execution of the previously-received commands and may remove the commands from the queue. To complete an execution of a write command, the controller may transfer data associated with the write command that is being stored in the buffer 425 to a memory device for storage. Based on transferring the data from the buffer 425 to the memory device, the controller may update the value of the counter indicating the amount of space within the buffer that is available for storing data associated with write commands. For example, the controller may increment the value of the counter according to the size of the data (e.g., may add the size of the data to the value of the counter). Additionally, the controller may update the value of the counter indicating the amount of space within the buffer that is available for storing data associated with read commands (e.g., if the data associated with the write command is stored in the read and write buffer 410).

To complete an execution of a read command, the controller may transmit data associated with the read command that is being stored in the buffer 425 to the host system. Based on transmitting the data from the buffer 425 to the host system, the controller may update the value of the counter indicating the amount of space within the buffer that is available for storing data associated with read commands. For example, the controller may increment the value of the counter according to the size of the data (e.g., may add the size of the data to the value of the counter). Additionally, the controller may update the value of the counter indicating the amount of space within the buffer that is available for storing data associated with write commands (e.g., if the data associated with the write command is stored in the read and write buffer 410).

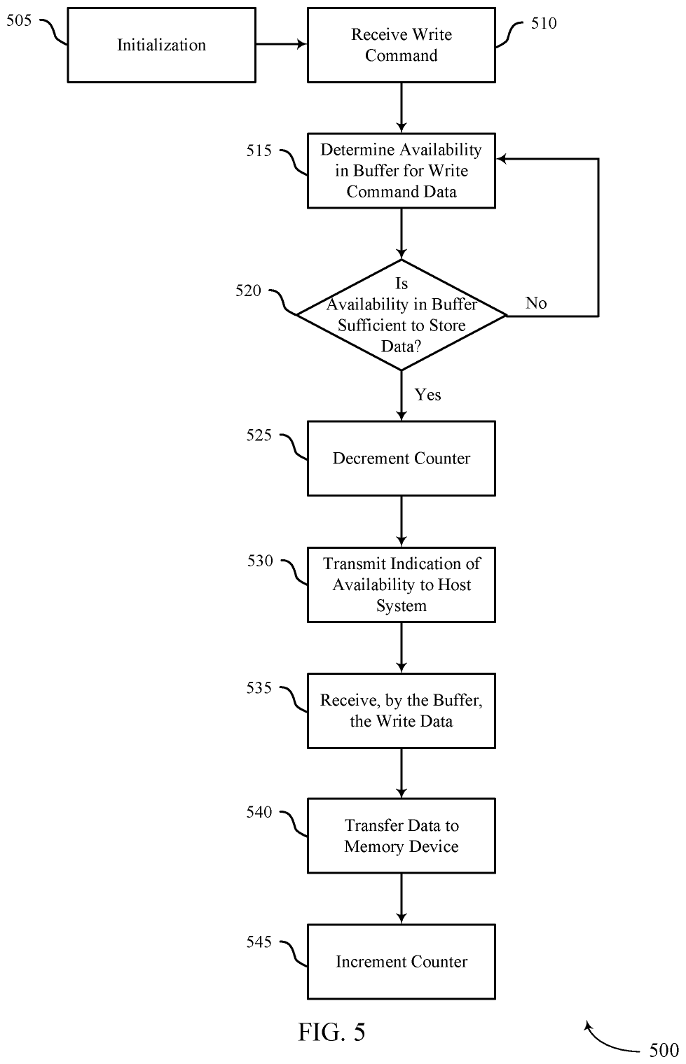

FIG. 5 illustrates an example of a flow diagram 500 that supports adaptive buffer partitioning in accordance with examples as disclosed herein. The flow diagram 500 may relate to an execution of a write command as described with reference to FIGS. 1 through 4. The operations of the flow diagram 500 may be performed by a memory system controller 115, a memory controller 255, or a memory system controller 315 as described with reference to FIGS. 1 through 3. Additionally, in some examples the flow diagram 500 may be implemented as instructions stored in memory (e.g., firmware stored in local memory 120 or other memory controller or memory systems as described herein). For example, the instructions, when executed by a controller (e.g., the memory system controller 315), may cause the controller to perform the operations of flow diagram 500.

At 505, an initialization procedure may be performed. For example, the memory system may perform one or more initialization procedures (e.g., after the memory system is powered on). During initialization, the memory system may determine a quantity of space available within the buffer for storing data associated with write commands. For example, the memory system may determine that the space within the buffer available for storing data associated with write commands is equal to the maximum write buffer size. The memory system may store a value indicating the amount of space within the buffer that is available for storing data associated with write commands.

At 510, a write command may be received. For example, the memory system receives, from a host system, a write command associated with a set of data.

At 515, an amount of available space for storing data associated with write commands at a buffer may be determined. For example, the memory system may determine the amount of space within a buffer configured to buffer data being transferred between the host system and a set of memory devices of a memory system that is available to store the set of data associated with the write command. In some cases, the amount of space may be based on a first portion of the buffer associated with read commands, a second portion of the buffer associated with write commands, and a third portion of the buffer associated with read commands and write commands. Additionally, the amount of space may be based on a first availability of space within the second portion of the buffer associated with write commands and a second availability of space within the third portion of the buffer associated with read commands and write commands.

At 520, the memory system may determine whether the amount of space within the buffer that is available to store the set of data is sufficient to store the set of data. If the memory system determines that the amount of space within the buffer that is available to store the set of data is sufficient to store the set of data, the memory system may proceed to 525. That is, the memory system may proceed to 525 in response to determining that the amount of space within the buffer that is available to store the set of data is sufficient to store the set of data. Alternatively, if the memory system determines that the amount of space within the buffer that is available to store the set of data is insufficient to store the set of data, the memory system may proceed to 515. That is, the memory system may proceed to 515 in response to determining that the amount of space within the buffer that is available to store the set of data is insufficient to store the set of data. In some cases, the memory system may (e.g., at 520) subsequently determine that an availability in the buffer is sufficient to store the set of data after another set of data has been transferred from the buffer (e.g., to a memory device, to a host system).

At 525, the value indicating the amount of space within the buffer that is available to store data (e.g., based on the size of the set of data) associated with the write command may be decremented (e.g., based on the size of the data).

At 530, an indication that the amount of space within the buffer is sufficient to store the set of data may be transmitted to the host system by the memory system. In some cases, the memory system may transmit the indication that the amount of space within the buffer is sufficient to store the set of data based on decrementing the value indicating the amount of space within the buffer that is available to store data associated with the write command.

At 535, the set of data may be received by the memory system from the host system based on transmitting the indication. Additionally, the memory system may add the write command associated with the set of data to a queue including a set of incomplete commands.

At 540, the set of data may be transferred from the buffer to a memory device of the set of memory devices based on receiving the set of data from the host system. In some cases, the memory system may then remove the write command associated with the set of data from the queue (e.g., based on completing an execution of the write command by transferring the set of data to the memory device).

At 545, the stored value indicating the amount of space within the buffer that is available to store data associated with the write command may be incremented (e.g., based on the size of the set of data) based on transferring the set of data to the memory device.

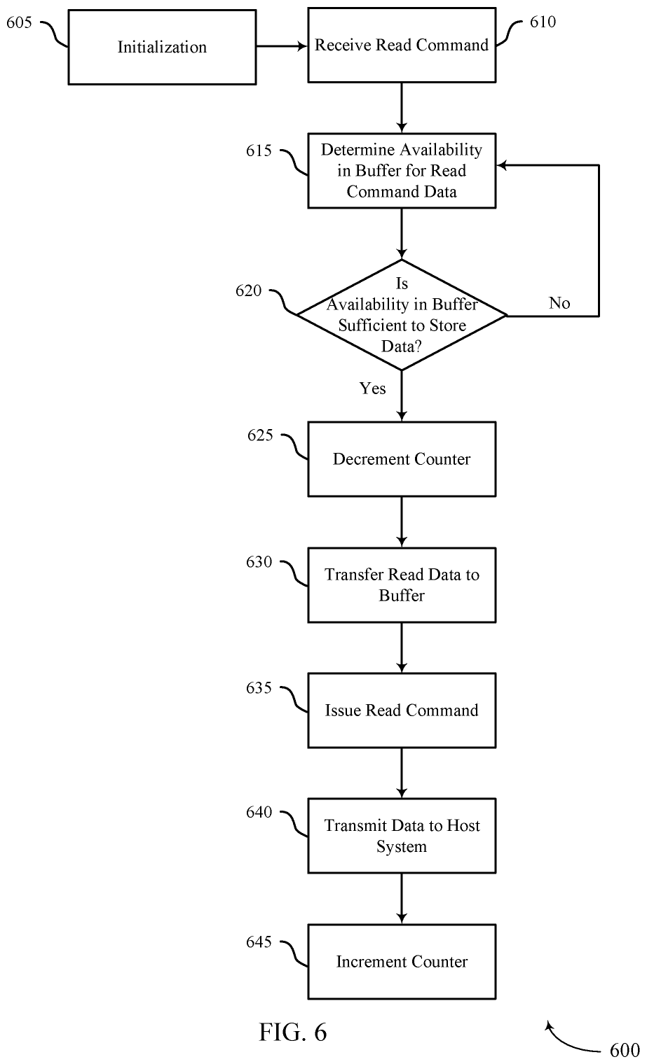

FIG. 6 illustrates an example of a flow diagram 600 that supports adaptive buffer partitioning in accordance with examples as disclosed herein. The flow diagram 600 may relate to an execution of a read command as described with reference to FIGS. 1 through 4. The operations of the flow diagram 600 may be performed by a memory system controller 115, a memory controller 255, or a memory system controller 315 as described with reference to FIGS. 1 through 3. Additionally, in some examples the flow diagram 600 may be implemented as instructions stored in memory (e.g., firmware stored in local memory 120 or other memory controller or memory systems as described herein). For example, the instructions, when executed by a controller (e.g., the memory system controller 315), may cause the controller to perform the operations of flow diagram 600.

At 605, an initialization procedure may be performed (e.g., after the memory system is powered on). During initialization, the memory system may determine a quantity of space available within the buffer for storing data associated with read commands. For example, the memory system may determine that the space within the buffer available for storing data associated with read commands is equal to the maximum read buffer size. The memory system may store a value indicating the amount of space within the buffer that is available for storing data associated with read commands.

At 610, a read command associated with a set of data may be received by the memory system from a host system.

At 615, an amount of space within a buffer configured to buffer data being transferred between a set of memory devices of a memory system and the host system that is available to store the set of data associated with the read command may be determined by the memory system. In some cases, the amount of space may be based on a first portion of the buffer associated with read commands, a second portion of the buffer associated with write commands, and a third portion of the buffer associated with read commands and write commands. Additionally, the amount of space may be based on a first availability of space within the first portion of the buffer associated with read commands and a second availability of space within the third portion of the buffer associated with read commands and write commands.

At 620, the memory system may determine whether the amount of space within the buffer that is available to store the set of data is sufficient to store the set of data. If the memory system determines that the amount of space within the buffer that is available to store the set of data is sufficient to store the set of data, the memory system may proceed to 625. That is, in response to determining that the amount of space within the buffer that is available to store the set of data is sufficient to store the set of data, the memory system may proceed to 625. Alternatively, if the memory system determines that the amount of space within the buffer that is available to store the set of data is insufficient to store the set of data, the memory system may proceed to 615. That is, in response to determining that the amount of space within the buffer that is available to store the set of data is insufficient to store the set of data, the memory system may proceed to 615. In some cases, the memory system may subsequently (e.g., at 620) determine that an availability in the buffer is sufficient to store the set of data after another set of data has been transferred from the buffer (e.g., to a memory device, to a host system).

At 625, the value indicating the amount of space within the buffer that is available to store data associated with the read command may be decremented (e.g., based on the size of the set of data).

At 630, the memory system may issue the read command to a memory device of a set of memory devices at the memory system based on determining that the amount of space within the buffer is sufficient to store the set of data. Additionally, the memory system may issue the read command based on decrementing the value indicating the amount of space within the buffer that is available to store data associated with the read command.

At 635, the set of data may be transferred from the memory device to the buffer based issuing the read command. In some cases, the memory device may transfer the data to the buffer based on decrementing the value indicating the amount of space within the buffer that is available to store data associated with the read command. Additionally, the memory system may add the read command associated with the set of data to a queue including a set of incomplete commands.

At 640, the set of data may be transmitted from the buffer to the host system based on transferring the data to the buffer. In some cases, the memory system may then remove the read command associated with the set of data from the queue (e.g., based on completing an execution of the read command by transferring the set of data to the host).

At 645, the stored value indicating the amount of space within the buffer that is available to store data associated with the read command may be incremented (e.g., based on the size of the set of data) based on transmitting the data to the host system.

FIG. 7 shows a block diagram 700 of a memory system 705 that supports adaptive buffer partitioning in accordance with examples as disclosed herein. The memory system 705 may be an example of aspects of a memory system as described with reference to FIGS. 1 through 6. The memory system 705 may include a command interface 710, an available space manager 715, a space indication manager 720, a data manager 725, and a value manager 730. Each of these modules may communicate, directly or indirectly, with one another (e.g., via one or more buses).

The command interface 710 may receive, from a host system, a write command associated with a set of data. Additionally, the command interface 710 may receive, from a host system, a read command associated with a set of data.

The available space manager 715 may determine, for a buffer configured to buffer data being transferred between the host system and a set of memory devices of a memory system, that an amount of space within the buffer that is available to store the set of data associated with the write command is sufficient to store the set of data. In some cases, the buffer may include a first portion of the buffer associated with read commands, a second portion of the buffer associated with write commands, and a third portion of the buffer associated with read commands and write commands. Here, the available space manager 715 may determine the amount of available space within the buffer based on the first, second, and/or third portions of the buffer. For example, the available space manager 715 may determine the amount of space within the buffer based on the portions of the buffer configured to stored data associated with the write command (e.g., the second portion and the third portion). In some instances, the available space manager 715 may determine the amount of space within the buffer based on the first portion of the buffer as well.

In some examples, the available space manager 715 may determine the amount of space within the buffer that is available to store the set of data associated with the write command based on a first availability of space within the second portion of the buffer associated with write commands and a second availability of space within the third portion of the buffer associated with read commands and write commands. In some cases, the first availability of space within the second portion of the buffer associated with write commands is based on an amount of data associated with a first queue including previously-received write commands. In some instances, the second availability of space with the third portion of the buffer associated with read commands and write commands is based on an amount of data associated with a second queue including previously received read commands and previously-received write commands. In some examples, the available space manager 715 may compare a size of the set of data to the value indicating the amount of space within the buffer that is available to store data associated with the write command, where determining that the amount of space within the buffer is sufficient to store the set of data is based on the comparing.

The available space manager 715 may determine, for a buffer configured to buffer data being transferred between a set of memory devices of a memory system and the host system, that an amount of space within the buffer that is available to store the set of data associated with the read command is sufficient to store the set of data. In some cases, the buffer may include a first portion of the buffer associated with read commands, a second portion of the buffer associated with write commands, and a third portion of the buffer associated with read commands and write commands. Here, the available space manager 715 may determine the amount of available space within the buffer that is available to store the set of data associated with the read command based on the first, second, and/or third portions of the buffer. For example, the available space manager 715 may determine the amount of space within the buffer based on the portions of the buffer configured to stored data associated with the read command (e.g., the first portion and the third portion). In some instances, the available space manager 715 may determine the amount of space within the buffer based on the second portion of the buffer as well.

In some examples, the available space manager 715 may determine the amount of space within the buffer that is available to store the set of data associated with the read command based on a first availability of space within the first portion of the buffer associated with read commands and a second availability of space within the third portion of the buffer associated with read commands and write commands. In some cases, the first availability of space within the first portion of the buffer associated with read commands is based on an amount of data associated with a first queue including previously-received read commands. In some instances, the second availability of space with the third portion of the buffer associated with read commands and write commands is based on an amount of data associated with a second queue including previously received read commands and previously-received write commands. In some examples, the available space manager 715 may compare a size of the set of data to the value indicating the amount of space within the buffer that is available to store data associated with the read command, where determining that the amount of space within the buffer is sufficient to store the set of data is based on the comparing.

The space indication manager 720 may transmit, to the host system, an indication that the amount of space within the buffer is sufficient to store the set of data (e.g., that is associated with a write command). Additionally, the space indication manager 720 may issue a read command to a memory device of the set of memory devices based on the amount of space within the buffer being sufficient to store the set of data (e.g., that is associated with a read command).

The data manager 725 may receive, by the buffer, the set of data from the host system based on transmitting the indication (e.g., that the amount of space within the buffer is sufficient to store the set of data associated with a write command). In some examples, the data manager 725 may transfer the set of data from the buffer to a memory device of the set of memory devices based on receiving the set of data from the host system.

The data manager 725 may transfer the set of data from the memory device to the buffer based on issuing the read command. In some examples, the data manager 725 may transmit the set of data from the buffer to the host system in accordance with the read command and based on transferring the set of data to the buffer.

The value manager 730 may store a value indicating the amount of space within the buffer that is available (e.g., for data associated with the write command). In some examples, the value manager 730 may update the value indicating the amount of space within the buffer that is available to store data associated with the write command, where transmitting the indication (e.g., that the amount of space within the buffer is sufficient to store the set of data associated with a write command) may be based on updating the value. Here, updating the value may include decrementing the value based on the size of the set of data. In some instances, the value manager 730 may update the value indicating the amount of space within the buffer that is available to store data associated with the write command based on transferring the set of data to the memory device. Here, updating the value may include incrementing the value based on a size of the set of data.

Additionally, the value manager 730 may store a value indicating the amount of space within the buffer that is available (e.g., for data associated with the read command). In some examples, the value manager 730 may update the value indicating the amount of space within the buffer that is available to store data associated with the read command, where transferring the set of data to the buffer may be based on updating the value. Here, updating the value may include decrementing the value based on the size of the set of data. In some cases, the value manager 730 may update the value stored indicating the amount of space within the buffer that is available to store data associated with the read command based on transmitting the set of data to the host system. Here, updating the value may include incrementing the value based on a size of the set of data.

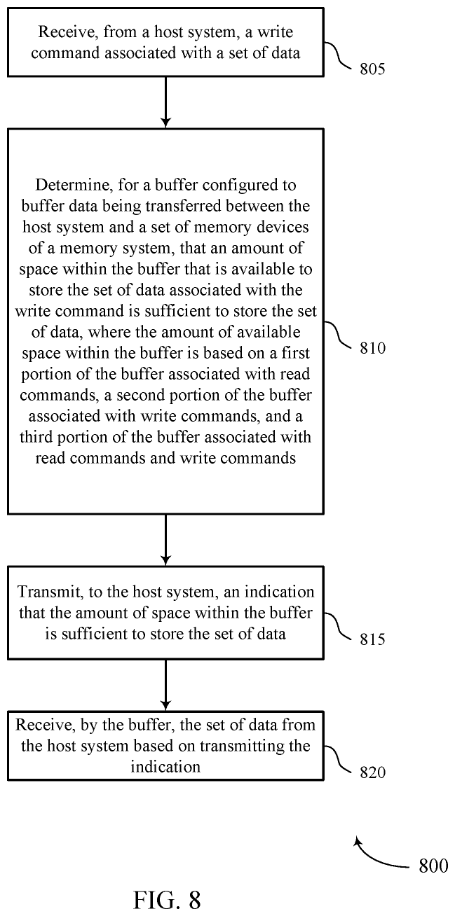

FIG. 8 shows a flowchart illustrating a method or methods 800 that supports adaptive buffer partitioning in accordance with aspects of the present disclosure. The operations of method 800 may be implemented by a memory system or its components as described herein. For example, the operations of method 800 may be performed by a memory system as described with reference to FIG. 7. In some examples, a memory system may execute a set of instructions to control the functional elements of the memory system to perform the described functions. Additionally or alternatively, a memory system may perform aspects of the described functions using special-purpose hardware.

At 805, the memory system may receive, from a host system, a write command associated with a set of data. The operations of 805 may be performed according to the methods described herein. In some examples, aspects of the operations of 805 may be performed by a command interface as described with reference to FIG. 7.

At 810, the memory system may determine, for a buffer configured to buffer data being transferred between the host system and a set of memory devices of a memory system, that an amount of space within the buffer that is available to store the set of data associated with the write command is sufficient to store the set of data, where the amount of available space within the buffer is based on a first portion of the buffer associated with read commands, a second portion of the buffer associated with write commands, and a third portion of the buffer associated with read commands and write commands. The operations of 810 may be performed according to the methods described herein. In some examples, aspects of the operations of 810 may be performed by an available space manager as described with reference to FIG. 7.

At 815, the memory system may transmit, to the host system, an indication that the amount of space within the buffer is sufficient to store the set of data. The operations of 815 may be performed according to the methods described herein. In some examples, aspects of the operations of 815 may be performed by a space indication manager as described with reference to FIG. 7.

At 820, the memory system may receive, by the buffer, the set of data from the host system based on transmitting the indication. The operations of 820 may be performed according to the methods described herein. In some examples, aspects of the operations of 820 may be performed by a data manager as described with reference to FIG. 7.

In some examples, an apparatus as described herein may perform a method or methods, such as the method 800. The apparatus may include features, means, or instructions (e.g., a non-transitory computer-readable medium storing instructions executable by a processor) for receiving, from a host system, a write command associated with a set of data, determining, for a buffer configured to buffer data being transferred between the host system and a set of memory devices of a memory system, that an amount of space within the buffer that is available to store the set of data associated with the write command is sufficient to store the set of data, where the amount of available space within the buffer is based on a first portion of the buffer associated with read commands, a second portion of the buffer associated with write commands, and a third portion of the buffer associated with read commands and write commands, transmitting, to the host system, an indication that the amount of space within the buffer is sufficient to store the set of data, and receiving, by the buffer, the set of data from the host system based on transmitting the indication.

Some examples of the method 800 and the apparatus described herein may further include operations, features, means, or instructions for determining the amount of space within the buffer that may be available to store the set of data associated with the write command based on a first availability of space within the second portion of the buffer associated with write commands and a second availability of space within the third portion of the buffer associated with read commands and write commands, and storing a value indicating the amount of space within the buffer that may be available.

Some cases of the method 800 and the apparatus described herein may further include operations, features, means, or instructions for comparing a size of the set of data to the value indicating the amount of space within the buffer that may be available to store data associated with the write command, where determining that the amount of space within the buffer is sufficient to store the set of data may be based on a result of the comparison.

Some instances of the method 800 and the apparatus described herein may further include operations, features, means, or instructions for updating the value indicating the amount of space within the buffer that may be available to store data associated with the write command, where transmitting the indication is based on updating the value.

In some examples of the method 800 and the apparatus described herein, updating the value may include operations, features, means, or instructions for decrementing the value based on the size of the set of data.

In some cases of the method 800 and the apparatus described herein, the first availability of space within the second portion of the buffer associated with write commands may be based on an amount of data associated with a first queue including previously-received write commands, and the second availability of space with the third portion of the buffer associated with read commands and write commands may be based on an amount of data associated with a second queue including previously received read commands and previously-received write commands.

Some instances of the method 800 and the apparatus described herein may further include operations, features, means, or instructions for transferring the set of data from the buffer to a memory device of the set of memory devices based on receiving the set of data from the host system.

Some examples of the method 800 and the apparatus described herein may further include operations, features, means, or instructions for updating the value indicating the amount of space within the buffer that may be available to store data associated with the write command based on transferring the set of data to the memory device.

In some cases of the method 800 and the apparatus described herein, updating the value may include operations, features, means, or instructions for incrementing the value based on a size of the set of data.

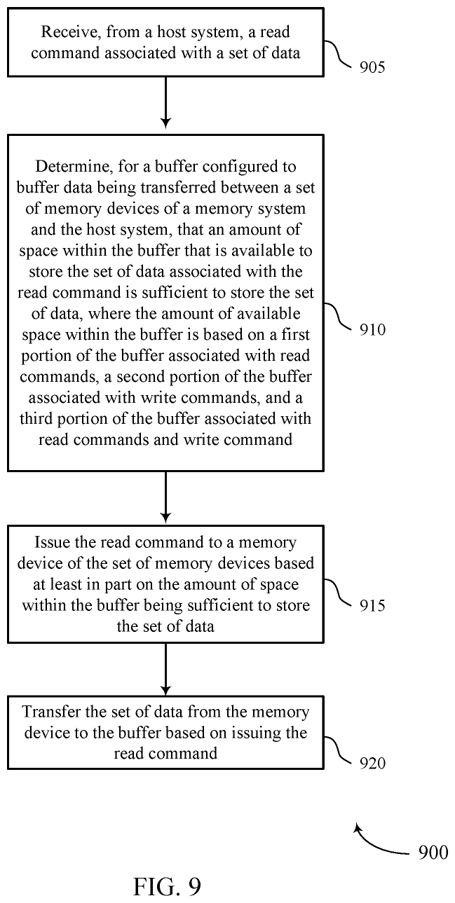

FIG. 9 shows a flowchart illustrating a method or methods 900 that supports adaptive buffer partitioning in accordance with aspects of the present disclosure. The operations of method 900 may be implemented by a memory system or its components as described herein. For example, the operations of method 900 may be performed by a memory system as described with reference to FIG. 7. In some examples, a memory system may execute a set of instructions to control the functional elements of the memory system to perform the described functions. Additionally or alternatively, a memory system may perform aspects of the described functions using special-purpose hardware.

At 905, the memory system may receive, from a host system, a read command associated with a set of data. The operations of 905 may be performed according to the methods described herein. In some examples, aspects of the operations of 905 may be performed by a command interface as described with reference to FIG. 7.

At 910, the memory system may determine, for a buffer configured to buffer data being transferred between a set of memory devices of a memory system and the host system, that an amount of space within the buffer that is available to store the set of data associated with the read command is sufficient to store the set of data, where the amount of available space within the buffer is based on a first portion of the buffer associated with read commands, a second portion of the buffer associated with write commands, and a third portion of the buffer associated with read commands and write commands. The operations of 910 may be performed according to the methods described herein. In some examples, aspects of the operations of 910 may be performed by an available space manager as described with reference to FIG. 7.

At 915, the memory system may issue the read command to a memory device of the set of memory devices based on the amount of space within the buffer being sufficient to store the set of data. The operations of 915 may be performed according to the methods described herein. In some examples, aspects of the operations of 915 may be performed by an available space manager as described with reference to FIG. 7.

At 920, the memory system may transfer the set of data from the memory device to the buffer based on issuing the read command. The operations of 920 may be performed according to the methods described herein. In some examples, aspects of the operations of 920 may be performed by a data manager as described with reference to FIG. 7.

In some examples, an apparatus as described herein may perform a method or methods, such as the method 900. The apparatus may include features, means, or instructions (e.g., a non-transitory computer-readable medium storing instructions executable by a processor) for receiving, from a host system, a read command associated with a set of data, determining, for a buffer configured to buffer data being transferred between a set of memory devices of a memory system and the host system, that an amount of space within the buffer that is available to store the set of data associated with the read command is sufficient to store the set of data, where the amount of available space within the buffer is based on a first portion of the buffer associated with read commands, a second portion of the buffer associated with write commands, and a third portion of the buffer associated with read commands and write commands, issuing the read command to a memory device of the set of memory devices based on the amount of space within the buffer being sufficient to store the set of data, and transferring the set of data from the memory device to the buffer based on issuing the read command.

Some examples of the method 900 and the apparatus described herein may further include operations, features, means, or instructions for determining the amount of space within the buffer that may be available to store the set of data associated with the read command based on a first availability of space within the first portion of the buffer associated with read commands and a second availability of space within the third portion of the buffer associated with read commands and write commands, and store a value indicating the amount of space within the buffer that may be available.

Some cases of the method 900 and the apparatus described herein may further include operations, features, means, or instructions for comparing a size of the set of data to the value indicating the amount of space within the buffer that may be available to store data associated with the read command, where determining that the amount of space within the buffer is sufficient to store the set of data may be based on a result of the comparison.

Some instances of the method 900 and the apparatus described herein may further include operations, features, means, or instructions for updating the value indicating the amount of space within the buffer that may be available to store data associated with the read command, where transferring the set of data to the buffer is based on updating the value.

In some examples of the method 900 and the apparatus described herein, updating the value may include operations, features, means, or instructions for decrementing the value based on the size of the set of data.

In some cases of the method 900 and the apparatus described herein, the first availability of space within the first portion of the buffer associated with read commands may be based on an amount of data associated with a first queue including previously-received read commands, and the second availability of space with the third portion of the buffer associated with read commands and write commands may be based on an amount of data associated with a second queue including previously received read commands and previously-received write commands.

Some instances of the method 900 and the apparatus described herein may further include operations, features, means, or instructions for transmitting the set of data from the buffer to the host system in accordance with the read command and based on transferring the set of data to the buffer.

Some examples of the method 900 and the apparatus described herein may further include operations, features, means, or instructions for updating the value stored indicating the amount of space within the buffer that may be available to store data associated with the read command based on transmitting the set of data to the host system.

In some cases of the method 900 and the apparatus described herein, updating the value may include operations, features, means, or instructions for incrementing the value based on a size of the set of data.

It should be noted that the methods described above describe possible implementations, and that the operations and the steps may be rearranged or otherwise modified and that other implementations are possible. Furthermore, portions from two or more of the methods may be combined.

An apparatus is described. The apparatus may include an interface in communication with a host system and configured to receive one or more read commands and one or more write commands from the host system, a set of memory devices configured to store one or more sets of data based on the one or more read commands and the one or more write commands, and a buffer coupled with the interface and the set of memory devices and configured to transfer the one or more sets of data between the interface and the set of memory devices according to the one or more read commands and one or more write commands, the buffer including a first portion configured to store data associated with the one or more read commands, a second portion configured to store data associated with the one or more write commands, and a third portion configured to store data associated with the one or more read commands and the one or more write commands.

Some examples of the apparatus may include a first counter configured to store a value indicating an amount of space within the second portion of the buffer and the third portion of the buffer that is available to store data associated with the one or more write commands.

Some cases of the apparatus may include decrement the value stored by the first counter based on storing data associated with the one or more write commands within the second portion of the buffer or the third portion of the buffer, and increment the value stored by the first counter based on transferring data associated with the one or more write commands from the buffer to a memory device of the set of memory devices.

Some instances of the apparatus may include a second counter configured to store a value indicating an amount of space within the first portion of the buffer and the third portion of the buffer that is available to store data associated with read commands.

Some examples of the apparatus may include decrement the value stored by the second counter based on storing data associated with the one or more read commands within the first portion of the buffer or the third portion of the buffer, and increment the value stored by the second counter based on transmitting data associated with the one or more read commands from the buffer to the host system.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, it will be understood by a person of ordinary skill in the art that the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to condition of moving from an open-circuit relationship between components in which signals are not presently capable of being communicated between the components over a conductive path to a closed-circuit relationship between components in which signals are capable of being communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial materials of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to providing an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The various illustrative blocks and modules described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described above can be implemented using software executed by a processor, hardware, firmware, hardwiring, or combinations of any of these. Features implementing functions may also be physically located at various positions, including being distributed such that portions of functions are implemented at different physical locations. Also, as used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.” When used to describe a conditional action or process, the terms “if,” “when,” “based on,” “based at least in part on,” and “in response to,” may be interchangeable.

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A non-transitory computer-readable medium storing code comprising instructions which, when executed by a processor of an electronic device, cause the electronic device to:
receive, from a host system, a write command associated with a set of data;
determine, for a buffer configured to buffer data being transferred between the host system and a set of memory devices of a memory system, that an amount of space within the buffer that is available to store the set of data is sufficient to store the set of data, wherein the amount of available space within the buffer is based at least in part on a first portion of the buffer associated with read commands, a second portion of the buffer associated with write commands, and a third portion of the buffer associated with read commands and write commands;
transmit, to the host system, an indication that the amount of space within the buffer is sufficient to store the set of data; and
receive, by the buffer, the set of data from the host system based at least in part on transmitting the indication.

2. The non-transitory computer-readable medium of claim 1, wherein the instructions, when executed by the processor of the electronic device, further cause the electronic device to:
determine the amount of space within the buffer that is available to store the set of data associated with the write command based at least in part on a first availability of space within the second portion of the buffer associated with write commands and a second availability of space within the third portion of the buffer associated with read commands and write commands; and
store a value indicating the amount of space within the buffer that is available.

3. The non-transitory computer-readable medium of claim 2, wherein the instructions, when executed by the processor of the electronic device, further cause the electronic device to:
compare a size of the set of data to the value indicating the amount of space within the buffer that is available to store data associated with the write command, wherein determining that the amount of space within the buffer is sufficient to store the set of data is based at least in part on the comparing.

4. The non-transitory computer-readable medium of claim 3, wherein the instructions, when executed by the processor of the electronic device, further cause the electronic device to:
update the value indicating the amount of space within the buffer that is available to store data associated with the write command, wherein transmitting the indication is based at least in part on updating the value.

5. The non-transitory computer-readable medium of claim 4, wherein the instructions to update the value further cause the electronic device to decrement the value based at least in part on the size of the set of data.

6. The non-transitory computer-readable medium of claim 2, wherein:
the first availability of space within the second portion of the buffer associated with write commands is based at least in part on an amount of data associated with a first queue comprising previously-received write commands; and
the second availability of space with the third portion of the buffer associated with read commands and write commands is based at least in part on an amount of data associated with a second queue comprising previously received read commands and previously-received write commands.

7. The non-transitory computer-readable medium of claim 2, wherein the instructions, when executed by the processor of the electronic device, further cause the electronic device to:
transfer the set of data from the buffer to a memory device of the set of memory devices based at least in part on receiving the set of data from the host system.

8. The non-transitory computer-readable medium of claim 7, wherein the instructions, when executed by the processor of the electronic device, further cause the electronic device to:
update the stored value indicating the amount of space within the buffer that is available to store data associated with the write command based at least in part on transferring the set of data to the memory device.

9. The non-transitory computer-readable medium of claim 8, wherein the instructions to update the value further cause the electronic device to increment the value based at least in part on a size of the set of data.

10. A non-transitory computer-readable medium storing code comprising instructions which, when executed by a processor of an electronic device, cause the electronic device to:
receive, from a host system, a read command associated with a set of data;
determine, for a buffer configured to buffer data being transferred between a set of memory devices of a memory system and the host system, that an amount of space within the buffer that is available to store the set of data associated with the read command is sufficient to store the set of data, wherein the amount of available space within the buffer is based at least in part on a first portion of the buffer associated with read commands, a second portion of the buffer associated with write commands, and a third portion of the buffer associated with read commands and write commands;
issue the read command to a memory device of the set of memory devices based at least in part on the amount of space within the buffer being sufficient to store the set of data; and
transfer the set of data from the memory device to the buffer based at least in part on issuing the read command.

11. The non-transitory computer-readable medium of claim 10, wherein the instructions, when executed by the processor of the electronic device, further cause the electronic device to:
determine the amount of space within the buffer that is available to store the set of data associated with the read command based at least in part on a first availability of space within the first portion of the buffer associated with read commands and a second availability of space within the third portion of the buffer associated with read commands and write commands; and
store a value indicating the amount of space within the buffer that is available.

12. The non-transitory computer-readable medium of claim 11, wherein the instructions, when executed by the processor of the electronic device, further cause the electronic device to:
compare a size of the set of data to the value indicating the amount of space within the buffer that is available to store data associated with the read command, wherein determining that the amount of space within the buffer is sufficient to store the set of data is based at least in part on the comparing.

13. The non-transitory computer-readable medium of claim 12, wherein the instructions, when executed by the processor of the electronic device, further cause the electronic device to:
update the value indicating the amount of space within the buffer that is available to store data associated with the read command, wherein transferring the set of data to the buffer is based at least in part on updating the value.

14. The non-transitory computer-readable medium of claim 13, wherein the instructions to update the value further cause the electronic device to decrement the value based at least in part on the size of the set of data.

15. The non-transitory computer-readable medium of claim 11, wherein:
the first availability of space within the first portion of the buffer associated with read commands is based at least in part on an amount of data associated with a first queue comprising previously-received read commands; and
the second availability of space with the third portion of the buffer associated with read commands and write commands is based at least in part on an amount of data associated with a second queue comprising previously received read commands and previously-received write commands.

16. The non-transitory computer-readable medium of claim 11, wherein the instructions, when executed by the processor of the electronic device, further cause the electronic device to:
transmit the set of data from the buffer to the host system in accordance with the read command and based at least in part on transferring the set of data to the buffer.

17. The non-transitory computer-readable medium of claim 16, wherein the instructions, when executed by the processor of the electronic device, further cause the electronic device to:
update the value indicating the amount of space within the buffer that is available to store data associated with the read command based at least in part on transmitting the set of data to the host system.

18. The non-transitory computer-readable medium of claim 17, wherein the instructions to update the value further cause the electronic device to increment the value based at least in part on a size of the set of data.

19. An apparatus, comprising:
an interface configured to communicate with a host system and configured to receive one or more read commands and one or more write commands from the host system;
a set of memory devices configured to store one or more sets of data based at least in part on the one or more read commands and the one or more write commands; and
a buffer coupled with the interface and the set of memory devices and configured to transfer the one or more sets of data between the interface and the set of memory devices according to the one or more read commands and one or more write commands, the buffer comprising:
a first portion configured to store data associated with the one or more read commands;
a second portion configured to store data associated with the one or more write commands; and
a third portion configured to store data associated with the one or more read commands and the one or more write commands.

20. The apparatus of claim 19, further comprising a first counter configured to store a value indicating an amount of space within the second portion of the buffer and the third portion of the buffer that is available to store data associated with the one or more write commands.

21. The apparatus of claim 20, further comprising a controller configured to:
decrement the value stored by the first counter based at least in part on storing data associated with the one or more write commands within the second portion of the buffer or the third portion of the buffer; and
increment the value stored by the first counter based at least in part on transferring data associated with the one or more write commands from the buffer to a memory device of the set of memory devices.

22. The apparatus of claim 19, further comprising a second counter configured to store a value indicating an amount of space within the first portion of the buffer and the third portion of the buffer that is available to store data associated with read commands.

23. The apparatus of claim 22, further comprising a controller configured to:
decrement the value stored by the second counter based at least in part on storing data associated with the one or more read commands within the first portion of the buffer or the third portion of the buffer; and
increment the value stored by the second counter based at least in part on transmitting data associated with the one or more read commands from the buffer to the host system.
